(19) United States
(12) Patent Application Publication
(10) Pub. No.: US 2024/0235484 A1
(43) Pub. Date: Jul. 11, 2024

(54) TRACKER MODULE AND COMMUNICATION DEVICE

(71) Applicant: Murata Manufacturing Co., Ltd., Nagaokakyo-shi (JP)

(72) Inventors: Takeshi KOGURE, Nagaokakyo-shi (JP); Tomohide ARAMATA, Nagaokakyo-shi (JP); Toshiki MATSUI, Nagaokakyo-shi (JP); Yuuki FUKUDA, Nagaokakyo-shi (JP)

(21) Appl. No.: 18/614,934

(22) Filed: Mar. 25, 2024

(30) Foreign Application Priority Data
Sep. 29, 2021 (JP) 2021-159966

(51) Int. Cl. H03F 1/02; H03F 3/24

(52) U.S. Cl. CPC H03F 1/0222; H03F 3/245; H03F 2200/105; H03F 2200/451

(57) ABSTRACT

A tracker module structure includes a module laminate, an integrated circuit disposed on the module laminate , and a plurality of capacitors that are disposed on the module laminate and includes one or more capacitors in a switched-capacitor circuit. The switched-capacitor circuit is configured to generate a plurality of discrete voltages. The integrated circuit includes a switch that is included in the switched-capacitor circuit and a switch that is included in the supply modulator. The plurality of capacitors include a first flying capacitor and a second flying capacitor that are configured to be charged and discharged in a complementary manner, and a third flying capacitor that is configured to be charged at a same timing as the first flying capacitor and be discharged at a same timing as the first flying capacitor. The second flying capacitor is disposed between the first flying capacitor and the third flying capacitor.

### CROSS REFERENCE TO RELATED APPLICATIONS

This application is a continuation of International Application No. PCT/JP2022/035993, filed Sep. 27, 2022, which claims priority to Japanese Patent Application No. 2021-159966, filed Sep. 29, 2021, the entire contents of each of which are hereby incorporated by reference in their entirety.

### TECHNICAL FIELD

The present disclosure relates to a tracker module and a communication device.

### BACKGROUND

In a related disclosure, such as U.S. Pat. No. 9,755,672 (hereinafter “Patent Document 1”), a power supply modulator circuit (e.g., an envelope tracking system) is provided. As described therein, the power supply modulator circuity is configured to supply a power supply voltage to a power amplifier circuit based on an envelope signal. The power supply modulator circuit includes a magnetic converter circuit (or magnetic regulation stage: pre-regulator circuit) that converts a voltage, a switched-capacitor circuit (or switched-capacitor voltage balancer stage) that generates a plurality of voltages having different voltage levels from the voltage, and a supply modulator (or an output switching stage) that selects and outputs at least one of the plurality of voltages. The magnetic converter circuit includes a switch and a power inductor. The switched-capacitor circuit includes switches and capacitors. The supply modulator includes a switch.

However, in the power supply modulator circuit according to Patent Document 1, when a tracker module is configured by mounting a switch integrated circuit that includes the switches of the switched-capacitor circuit and the switch of the supply modulator on a module laminate, large currents can generated. Moreover, the large currents can have rapid voltage changes that are caused by high-speed charging and discharging of the capacitors. The large currents can flow through a plurality of wires connecting the switches and the capacitors of the switched-capacitor circuit. Thus, large electromagnetic field noise may be generated because of interference between signals flowing among the plurality of wires.

### SUMMARY OF THE INVENTION

In view of the foregoing, the exemplary aspects of the present disclosure provide a tracker module and a communication device in which generation of electromagnetic field noise caused by signal interference between wires is suppressed.

According to an exemplary aspect of the disclosure, a tracker module (or tracker module structure) is provided. The tracker module includes a module laminate, an integrated circuit disposed on the module laminate, and a plurality of capacitors that are disposed on the module laminate and included in a switched-capacitor circuit and a supply modulator. The switched-capacitor circuit is configured to generate a plurality of discrete voltages based on an input voltage. The integrated circuit includes a switch that is included in the switched-capacitor circuit and a switch that is included in the supply modulator. The supply modulator is configured to selectively output at least one of the plurality of discrete voltages generated by the switched-capacitor circuit. The plurality of capacitors includes a first flying capacitor and a second flying capacitor that are charged and discharged in a complementary manner by repeating a first phase and a second phase between the first flying capacitor and the second flying capacitor. The plurality of capacitor further includes a third flying capacitor that is charged at a same timing as the first flying capacitor and discharged at a same timing as the first flying capacitor. The second flying capacitor is disposed between the first flying capacitor and the third flying capacitor.

According to another exemplary aspect of the present disclosure, a tracker module is provided. The tracker module includes a module laminate, a first circuit and a second circuit. The first circuit is configured to generate a plurality of discrete voltages based on an input voltage. The second circuit is configured to selectively output at least one of the plurality of discrete voltages generated by the first circuit. According to an exemplary aspect, the first circuit includes a first capacitor including a first electrode and a second electrode, a second capacitor including a third electrode and a fourth electrode, a third capacitor including a fifth electrode and a sixth electrode, a first switch, a second switch, a third switch, a fourth switch, a fifth switch, a sixth switch, a seventh switch, and an eighth switch. One end of the first switch and one end of the third switch are connected (or coupled) to the first electrode. One end of the second switch and one end of the fourth switch are connected (or coupled) to the second electrode and the fifth electrode. One end of the fifth switch and one end of the seventh switch are connected (or coupled) to the third electrode. One end of the sixth switch and one end of the eighth switch are connected (or coupled) to the fourth electrode. Another end of the first switch, another end of the second switch, another end of the fifth switch, and another end of the sixth switch are connected (or coupled) to each other. Another end of the third switch is connected (or coupled) to another end of the seventh switch. Another end of the fourth switch is connected (or coupled) to another end of the eighth switch. According to an exemplary aspect, the second circuit includes a first output terminal, a ninth switch, and a tenth switch. The ninth switch is connected between (or coupled to) (i) the first output terminal and (ii) the other end of the first switch, the other end of the second switch, the other end of the fifth switch, and the other end of the sixth switch. The tenth switch is connected between (or coupled to) (i) the first output terminal and (ii) the other end of the third switch and the other end of the seventh switch. The first switch, the second switch, the third switch, the fourth switch, the fifth switch, the seventh switch, the eighth switch, the ninth switch, and the tenth switch are included in an integrated circuit. The first capacitor, the second capacitor, the third capacitor, and the integrated circuit are disposed on the module laminate. The second capacitor is disposed between the first capacitor and the third capacitor.

According to the present disclosure, a tracker module and/or a communication device can be provided. In the disclosed tracker module and/or the communication device, generation of electromagnetic field noise caused by signal interference between wires is suppressed.

### BRIEF DESCRIPTION OF DRAWINGS

FIG. 1 is a circuit block diagram of a power supply circuit and a communication device according to an exemplary embodiment.

FIG. 2A is a graph illustrating an example of transition of a power supply voltage in a digital ET mode.

FIG. 2B is a graph illustrating an example of transition of the power supply voltage in an analog ET mode.

FIG. 3 is a diagram illustrating a circuit configuration example of the power supply circuit according to the embodiment.

FIG. 4 is a plan view of a tracker module according to Example 1.

FIG. 5 is a first cross-sectional view of the tracker module according to Example 1.

FIG. 6 is a second cross-sectional view of the tracker module according to Example 1.

FIG. 7 is a plan view of a tracker module according to Example 2.

FIG. 8 is a plan view of a tracker module according to Example 3.

### DETAILED DESCRIPTION OF EMBODIMENTS

Hereinafter, an exemplary embodiment of the present disclosure will be described in detail using the drawings. It is noted that any embodiment described below illustrates a comprehensive or specific example. Numerical values, shapes, materials, constituents, a disposition and a connection form of the constituents, and the like illustrated in the following embodiment are examples and not intended to limit the present disclosure.

Each drawing is a schematic diagram that is highlighted, omitted, or adjusted in ratio, as appropriate, to illustrate the exemplary aspects of the present disclosure and is not necessarily illustrated in a strict sense. Each drawing may have different shapes, positional relationships, and ratios from those in actuality. Substantially the same configurations are designated by the same reference signs in each drawing, and duplicate descriptions may be omitted or simplified.

In each drawing below, an x-axis and a y-axis are axes that are orthogonal to each other on a plane parallel to a main surface of a module laminate. For example, when the module laminate has a rectangular shape in a plan view, the x-axis is parallel to a first edge of the module laminate, and the y-axis is parallel to a second edge of the module laminate that is orthogonal to the first edge. In addition, a z-axis is an axis perpendicular to the main surface of the module laminate. A positive direction of the z-axis indicates an upward direction, and a negative direction of the z-axis indicates a downward direction.

In addition, in the following embodiment, the term “connected” includes not only a case of being directly connected through a connection terminal and/or a wire conductor, but also a case of being electrically connected through other circuit elements. Moreover, for purpose of this disclosure, the expression “connected between A and B” means being connected to both A and B directly through a connection terminal and/or a wire conductor or means being connected to both A and B indirectly through a connection path connecting A to B.

In addition, in the component disposition of the present disclosure, the expression “A is disposed on the main surface of the laminate” not only means that A is directly mounted on the main surface, but also means that A is disposed in a space on the main surface side out of the space on the main surface side and a space on a side opposite to the main surface divided by the laminate. That is, mounting A on the main surface with other circuit components, electrodes, and the like interposed therebetween is included.

In addition, in the component disposition of the present disclosure, the term “plan view” means viewing an object orthogonally projected to an xy plane from a positive side of the z-axis.

In addition, in the component disposition of the present disclosure, for A, B, and C disposed on the laminate, the expression “C is disposed between A and B” means that at least one of a plurality of line segments connecting any point in A to any point in B passes through a region of C.

In addition, in the component disposition of the present disclosure, a plan view of the laminate means a view of the laminate and circuit elements mounted on the laminate that are orthogonally projected to a plane parallel to the main surface of the laminate.

In addition, in the component disposition of the present disclosure, the expression “A and B are adjacent to each other” means that A and B are disposed close to each other. For example, the expression means that a circuit component is not present in a space in which A and B face each other. In other words, this means that any of a plurality of line segments that reach B along a direction normal to a surface of A facing B from any point on the surface does not pass through a circuit component other than A and B. The circuit component includes active components such as a transistor and a diode and passive components such as an inductor, a transformer, a capacitor, and a resistor and does not include a terminal, a connector, an electrode, a wire, a resin member, and the like.

In addition, in the present disclosure, terms such as “parallel” and “perpendicular” indicates a relationship between elements, and terms such as “rectangular” indicates a shape of an element which not only represents a strict meaning but also means that a substantially equivalent range including. For example, an error of approximately a few % is included.

In addition, in the present disclosure, the term “signal path” means a transmission line configured with a wire through which a radio frequency signal propagates, an electrode directly connected to the wire, a terminal directly connected to the wire or to the electrode, and the like.

### 1 Circuit Configuration of Power Supply Circuit 1 and Communication Device 7

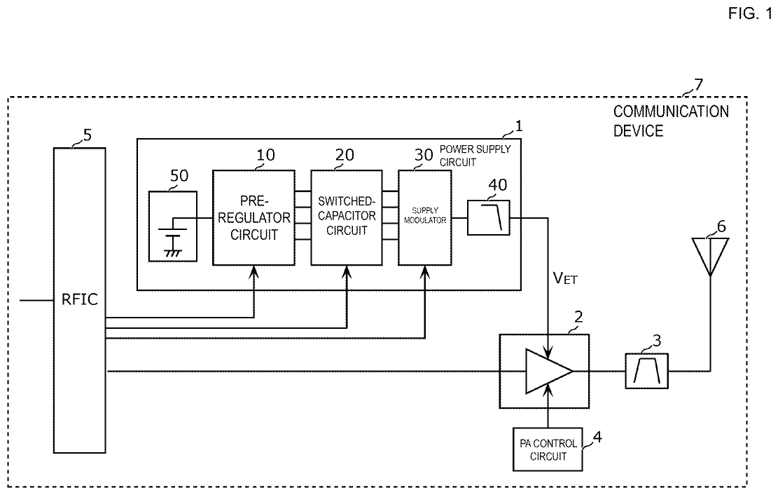

Circuit configurations of a power supply circuit 1 and a communication device 7 according to the present disclosure will be described with reference to FIG. 1. FIG. 1 is a circuit block diagram of the power supply circuit 1 and the communication device 7 according to the disclosure.

### 1.1 Circuit Configuration of Communication Device 7

As illustrated in FIG. 1, the communication device 7 according to the present disclosure includes the power supply circuit 1, a power amplifier circuit 2, a filter 3, a PA control circuit 4, a radio frequency integrated circuit (RFIC) 5, and an antenna 6.

In an exemplary aspect, the power supply circuit 1 includes a pre-regulator circuit 10, a switched-capacitor circuit 20, a supply modulator 30, a filter circuit 40, and a direct current power source 50.

The power supply circuit 1 supplies a power supply voltage V_{ET} having a power supply voltage level selected from a plurality of discrete voltage levels based on an envelope signal to the power amplifier circuit 2. In FIG. 1, one power supply circuit, such as the power supply circuity 1, supplies one power supply voltage V_{ET} to one power amplifier circuit, such as the power amplifier circuity 2. However, FIG. 1 is merely an example, a plurality of power supply voltages may be individually supplied to a plurality of power amplifiers.

The pre-regulator circuit 10 is an example of a third circuit and includes a power inductor and a switch. The power inductor is an inductor used for stepping up and/or stepping down a direct current voltage. The power inductor is disposed in series on a direct current path. The pre-regulator circuit 10 can convert an input voltage (or a third voltage) into a first voltage using the power inductor. The pre-regulator circuit 10 may be referred to as a magnetic regulator or a direct current (DC)/DC converter. The power inductor may be connected (e.g., disposed in parallel) between a series path and a ground.

In an exemplary aspect, the pre-regulator circuit 10 not including a power inductor may be used. For example, the pre-regulator circuit 10 may be a circuit that executes the step-up by switching between capacitors disposed on each of a series arm path and a parallel arm path of the pre-regulator circuit 10.

The switched-capacitor circuit 20 is an example of a first circuit and includes a plurality of capacitors and a plurality of switches. The switched-capacitor circuit 20 can generate a plurality of second voltages including the plurality of discrete voltage levels, respectively, from the first voltage generated from the pre-regulator circuit 10. The switched-capacitor circuit 20 may be referred to as a switched-capacitor voltage balancer.

The supply modulator 30 is an example of a second circuit and can selectively output at least one of a plurality of discrete voltages (or the plurality of second voltages) generated by the switched-capacitor circuit 20 to the filter circuit 40 based on a digital control signal corresponding to the envelope signal. Consequently, at least one voltage selected from the plurality of discrete voltages is output from the supply modulator 30. The supply modulator 30 can change the output voltage over time by repeating selection of the voltage over time.

The supply modulator 30 may include various circuit elements and/or wires that cause a voltage drop and/or a noise and the like. Thus, a time waveform of the output voltage of the supply modulator 30 may not be a rectangular wave and may not include the plurality of discrete voltages. That is, the output voltage of the supply modulator 30 may include a voltage different from the plurality of discrete voltages.

The filter circuit 40 can filter signals (e.g., second voltages) from the supply modulator 30. The filter circuit 40 is configured with, for example, a low pass filter (LPF).

The direct current power source 50 can supply a direct current voltage to the pre-regulator circuit 10. For example, a rechargeable battery can be used as the direct current power source 50. However, the direct current power source 50 is not limited thereto.

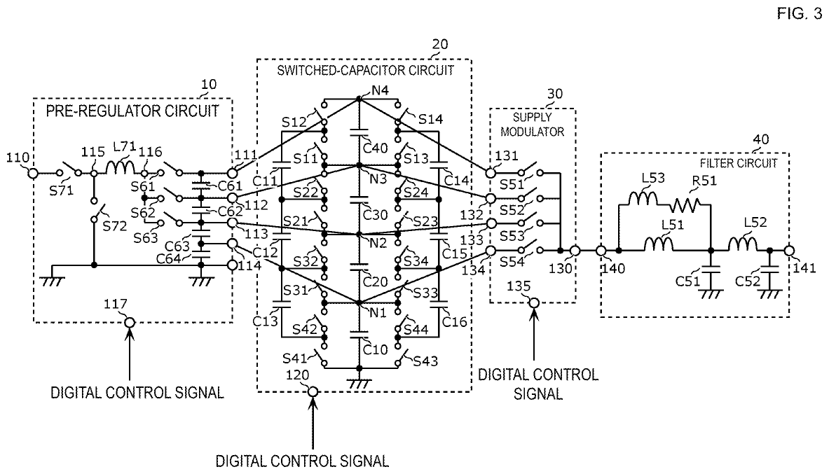

In an exemplary aspect, the power supply circuit 1 may not include one of the pre-regulator circuit 10, the filter circuit 40, and the direct current power source 50. For example, the power supply circuit 1 may not include the filter circuit 40 and the direct current power source 50. In addition, any combination of the pre-regulator circuit 10, the switched-capacitor circuit 20, the supply modulator 30, and the filter circuit 40 may be integrated into a single circuit. A detailed circuit configuration example of the power supply circuit 1 will be described later using FIG. 3.

The power amplifier circuit 2 is connected (or coupled) between the RFIC 5 and the filter 3, amplifies a radio frequency transmission signal (hereinafter, referred to as a transmission signal) of a predetermined band output from the RFIC 5, and outputs the amplified transmission signal to the antenna 6 through the filter 3.

The PA control circuit 4 receives a control signal from the RFIC 5 to control a magnitude and a supply timing of a bias current (or a bias voltage) that is to be supplied to the power amplifier circuit 2.

As illustrated in FIG. 1, the filter 3 is connected (or coupled) between the power amplifier circuit 2 and the antenna 6. The filter 3 has a passband including the predetermined band. Accordingly, the transmission signal of the predetermined band amplified by the power amplifier circuit 2 can pass through the filter 3.

The antenna 6 is connected to an output side of the power amplifier circuit 2 and transmits the transmission signal of the predetermined band output from the power amplifier circuit 2.

The RFIC 5 is an example of a signal processing circuit that processes a radio frequency signal. For example, the RFIC 5 performs signal processing such as upconversion on a transmission signal input from a baseband signal processing circuit (e.g., BBIC; not illustrated) and outputs the transmission signal generated through the signal processing to the power amplifier circuit 2.

In an aspect, the RFIC 5 is an example of a control circuit and includes a control unit that controls the power supply circuit 1 and the power amplifier circuit 2. The RFIC 5 causes the supply modulator 30 to select the voltage level of the power supply voltage V_{ET} from the plurality of discrete voltage levels. The power supply voltage V_{ET} can be used in the power amplifier circuit 2. The plurality of discrete voltage levels can be generated by the switched-capacitor circuit 20 based on the envelope signal of the radio frequency input signal obtained from the BBIC. Accordingly, the power supply circuit 1 outputs the power supply voltage V_{ET} based on digital envelope tracking.

A part or all of functions of the RFIC 5 as the control unit may be present outside the RFIC 5. For example, the part or all of functions of the RFIC 5 may be provided in the BBIC or the power supply circuit 1. In an example, a control function of selecting the power supply voltage V_{ET} may be provided in the power supply circuit 1 instead of the RFIC 5.

The envelope signal is a signal indicating an envelope of the radio frequency input signal (modulated signal). An envelope value is represented by, for example, √(i₂+Q₂). Here, (I, Q) represents a constellation point. The constellation point is a point representing a signal modulated by digital modulation on a constellation diagram. (I, Q) is determined by the BBIC based on, for example, transmission information.

Tracking the envelope of the radio frequency signal using the plurality of discrete voltage levels in one frame is referred to as the digital envelope tracking (hereinafter, referred to as digital ET), and a mode in which the digital ET is applied to the power supply voltage is referred to as a digital ET mode. In addition, tracking the envelope of the radio frequency signal using a continuous voltage level is referred to as analog envelope tracking (hereinafter, referred to as analog ET), and a mode in which the analog ET is applied to the power supply voltage is referred to as an analog ET mode.

The frame represents a unit forming the radio frequency signal (e.g., a modulated signal). For example, in 5th Generation New Radio (5G NR) and Long Term Evolution (LTE), the frame has 10 subframes, each subframe has a plurality of slots, and each slot is configured with a plurality of symbols. A subframe length is 1 ms, and a frame length is 10 ms.

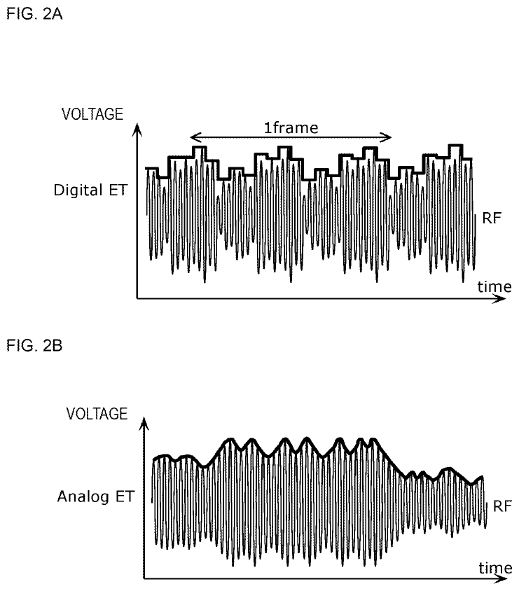

In an example, the digital ET mode and the analog ET mode can be described with reference to FIGS. 2A and 2B.

FIG. 2A is a graph illustrating an example of transition of the power supply voltage in the digital ET mode. FIG. 2B is a graph illustrating an example of transition of the power supply voltage in the analog ET mode. In FIGS. 2A and 2B, a horizontal axis represents time, and a vertical axis represents a voltage. In addition, a thick solid line represents the power supply voltage V_{ET}, and a thin solid line (or waveform) represents the modulated signal.

In the digital ET mode, as illustrated in FIG. 2A, the envelope of the modulated signal is tracked by changing the power supply voltage V_{ET} to the plurality of discrete voltage levels in one frame. Consequently, a power supply voltage signal forms a rectangular wave. In the digital ET mode, the power supply voltage level is selected from the plurality of discrete voltage levels based on the envelope signal (√(i₂+Q₂)).

In the analog ET mode, as illustrated in FIG. 2B, the envelope of the modulated signal is tracked by continuously changing the power supply voltage V_{ET}. In the analog ET mode, the power supply voltage V_{ET} is determined based on the envelope signal. In the analog ET, the power supply voltage V_{ET} can follow the change in the envelope of the modulated signal when a channel band width is relatively small (for example, less than 60 MHz). However, when the channel band width is relatively large (for example, 60 MHz or greater), the power supply voltage V_{ET} cannot follow the change in the envelope of the modulated signal. In other words, when the channel band width is relatively large, a change in an amplitude of the power supply voltage V_{ET} is delayed with respect to the change in the envelope of the modulated signal.

In an exemplary aspect, when the channel band width is relatively large (for example, 60 MHz or greater), ability of the power supply voltage V_{ET} to follow the modulated signal is improved by applying the digital ET mode, as illustrated in FIG. 2A.

The communication device 7 illustrated in FIG. 1 is an example, and the present disclosure is not limited thereto. For example, the communication device 7 may not include the filter 3, the PA control circuit 4, and the antenna 6. Furthermore, the communication device 7 may include a low-noise amplifier and a receive path that includes a receive filter. In addition, for example, the communication device 7 may include a plurality of power amplifier circuits corresponding to different bands.

### 1.2 Circuit Configuration of Power Supply Circuit 1

In an exemplary aspect, circuit configurations of the pre-regulator circuit 10, the switched-capacitor circuit 20, the supply modulator 30, and the filter circuit 40 included in the power supply circuit 1 will be described with reference to FIG. 3. FIG. 3 is a diagram illustrating a circuit configuration example of the power supply circuit 1 according to an exemplary embodiment of the disclosure.

FIG. 3 is an exemplary circuit configuration, and the pre-regulator circuit 10, the switched-capacitor circuit 20, the supply modulator 30, and the filter circuit 40 may be mounted using any of various circuit mounting and circuit technologies. Accordingly, description of each circuit provided below is not to be interpreted as being limiting.

### 1.2.1 Circuit Configuration of Switched-Capacitor Circuit 20

The circuit configuration of the switched-capacitor circuit 20 can be provided in FIG. 3. As illustrated in FIG. 3, the switched-capacitor circuit 20 includes capacitors C11, C12, C13, C14, C15, C16, C10, C20, C30, and C40, switches S11, S12, S13, S14, S21, S22, S23, S24, S31, S32, S33, S34, S41, S42, S43, and S44, and a control terminal 120. It should be noted that Fig. is merely an example. The switched-capacitor circuit 20 can include any other capacitors, switches, or components.

The control terminal 120 is an input terminal of the digital control signal. In an aspect, the control terminal 120 is a terminal for receiving the digital control signal to control the switched-capacitor circuit 20. For example, a control signal of a source-synchronous scheme for transmitting a data signal and a clock signal can be used as the digital control signal received through the control terminal 120. However, the digital control signal is not limited thereto. For example, a clock-embedded scheme may be applied to the digital control signal.

Each of the capacitors C11 to C16 functions as a flying capacitor (may be referred to as a transfer capacitor). In an example, each of the capacitors C11 to C16 is used for stepping up or stepping down the first voltage supplied from the pre-regulator circuit 10. In an example, the capacitors C11 to C16 cause charges to move between the capacitors C11 to C16 and nodes N1 to N4 such that voltages V1 to V4 (e.g., voltages with respect to a ground potential) satisfying V1:V2:V3:V4=1:2:3:4 are maintained among the four nodes N1 to N4. Each of the voltages V1 to V4 corresponding to the plurality of second voltages can have a respective one of the plurality of discrete voltage levels (or respective discrete voltage level).

The capacitor C11 is an example of a third capacitor and includes two electrodes (e.g., a fifth electrode and a sixth electrode). One (e.g., fifth electrode) of the two electrodes of the capacitor C11 is connected (or coupled) to one end of the switch S11 and one end of the switch S12. Another (e.g., sixth electrode) of the two electrodes of the capacitor C11 is connected (or coupled) to one end of the switch S21 and one end of the switch S22. For purposes of this disclosure the term “one end” may generally be considered a “first end” and the term “another end” or the “other end” may generally be considered a “second end”.

The capacitor C12 is an example of a first capacitor and includes two electrodes (e.g., a first electrode and a second electrode). One of the two electrodes of the capacitor C12 is connected to one end of the switch S21 and one end of the switch S22. Another of the two electrodes of the capacitor C12 is connected to one end of the switch S31 and one end of the switch S32.

The capacitor C13 is an example of the third capacitor and includes two electrodes (e.g., the fifth electrode and the sixth electrode). One (e.g., fifth electrode) of the two electrodes of the capacitor C13 is connected to one end of the switch S31 and one end of the switch S32. Another (e.g., sixth electrode) of the two electrodes of the capacitor C13 is connected to one end of the switch S41 and one end of the switch S42.

The capacitor C14 is an example of a second capacitor and includes two electrodes (e.g., a third electrode and a fourth electrode). One of the two electrodes of the capacitor C14 is connected to one end of the switch S13 and one end of the switch S14. Another of the two electrodes of the capacitor C14 is connected to one end of the switch S23 and one end of the switch S24.

The capacitor C15 is an example of the second capacitor and includes two electrodes (e.g., the third electrode and the fourth electrode). One of the two electrodes of the capacitor C15 is connected to one end of the switch S23 and one end of the switch S24. Another of the two electrodes of the capacitor C15 is connected to one end of the switch S33 and one end of the switch S34.

The capacitor C16 includes two electrodes. One of the two electrodes of the capacitor C16 is connected to one end of the switch S33 and one end of the switch S34. Another of the two electrodes of the capacitor C16 is connected to one end of the switch S33 and one end of the switch S34.

The capacitors C11 and C13 are also examples of the first capacitor, and the capacitors C14 and C16 are also examples of the second capacitor.

Each of a set of the capacitors C11 and C14, a set of the capacitors C12 and C15, and a set of the capacitors C13 and C16 can be charged and discharged in a complementary manner by repeating a first phase and a second phase.

In an example, in the first phase, the switches S12, S13, S22, S23, S32, S33, S42, and S43 are ON. Accordingly, for example, one of the two electrodes of the capacitor C12 is connected to the node N3, the other of the two electrodes of the capacitor C12 and one of the two electrodes of the capacitor C15 are connected to the node N2, and the other of the two electrodes of the capacitor C15 is connected to the node N1.

In an example, in the second phase, the switches S11, S14, S21, S24, S31, S34, S41, and S44 are ON. Accordingly, for example, one of the two electrodes of the capacitor C15 is connected to the node N3, the other of the two electrodes of the capacitor C15 and one of the two electrodes of the capacitor C12 are connected to the node N2, and the other of the two electrodes of the capacitor C12 is connected to the node N1.

By repeating the first phase and the second phase, for example, one of the capacitors C12 and C15 can be discharged to the capacitor C30 while the other of the capacitors C12 and C15 is being charged from the node N2. Thus, the capacitors C12 and C15 can be charged and discharged in a complementary manner. The capacitors C12 and C15 are a pair of flying capacitors that are charged and discharged in a complementary manner.

A set of any of the capacitors C11, C12, and C13 (or first capacitor) and any of C14, C15, and C16 (or second capacitor) is also a pair of flying capacitors like the set of the capacitors C12 and C15 that are charged from a node and discharged to a smoothing capacitor in a complementary manner by appropriately switching the switches.

Each of the capacitors C10, C20, C30, and C40 functions as a smoothing capacitor. That is, each of the capacitors C10, C20, C30, and C40 is configured to hold and smoothen the voltages V1 to V4 in the nodes N1 to N4.

The capacitor C10 is connected between the node N1 and the ground. In an example, one of two electrodes of the capacitor C10 is connected to the node N1. In an example, the other of the two electrodes of the capacitor C10 is connected to the ground.

The capacitor C20 is an example of a fourth capacitor and includes two electrodes (e.g., a seventh electrode and an eighth electrode). One (e.g., the seventh electrode) of the two electrodes of the capacitor C20 is connected to the node N2, the other end of the switch S21, the other end of the switch S32, the other end of the switch S23, and the other end of the switch S34. Another (e.g., the eighth electrode) of the two electrodes of the capacitor C20 is connected to the node N1, the other end of the switch S31, and the other end of the switch S33.

The capacitor C30 is an example of the fourth capacitor and includes two electrodes (e.g., the seventh electrode and the eighth electrode). One (e.g., the seventh electrode) of the two electrodes of the capacitor C30 is connected to the node N2, the other end of the switch S21, the other end of the switch S32, the other end of the switch S23, and the other end of the switch S34. Another (e.g., the eighth electrode) of the two electrodes of the capacitor C30 is connected to the node N3, the other end of the switch S22, and the other end of the switch S24.

The capacitor C40 is connected between the nodes N4 and N3. In an example, one of two electrodes of the capacitor C40 is connected to the node N4. In an example, the other of the two electrodes of the capacitor C40 is connected to the node N3.

The switch S11 is connected between one of the two electrodes of the capacitor C11 and the node N3. In an example, one end of the switch S11 is connected to one of the two electrodes of the capacitor C11. In an example, the other end of the switch S11 is connected to the node N3.

The switch S12 is connected between one of the two electrodes of the capacitor C11 and the node N4. In an example, one end of the switch S12 is connected to one of the two electrodes of the capacitor C11. In an example, the other end of the switch S12 is connected to the node N4.

The switch S21 is an example of a first switch and is connected between one of the two electrodes of the capacitor C12 and the node N2. In an example, one end of the switch S21 is connected to one of the two electrodes of the capacitor C12 and the other of the two electrodes of the capacitor C11. In an example, the other end of the switch S21 is connected to the node N2.

The switch S22 is an example of a third switch and is connected between one of the two electrodes of the capacitor C12 and the node N3. In an example, one end of the switch S22 is connected to one of the two electrodes of the capacitor C12 and the other of the two electrodes of the capacitor C11. In an example, the other end of the switch S22 is connected to the node N3.

The switch S31 is an example of a fourth switch and is connected between the other of the two electrodes of the capacitor C12 and the node N1. In an example, one end of the switch S31 is connected to the other of the two electrodes of the capacitor C12 and one of the two electrodes of the capacitor C13. In an example, the other end of the switch S31 is connected to the node N1.

The switch S32 is an example of a second switch and is connected between the other of the two electrodes of the capacitor C12 and the node N2. In an example, one end of the switch S32 is connected to the other of the two electrodes of the capacitor C12 and one of the two electrodes of the capacitor C13. In an example, the other end of the switch S32 is connected to the node N2. That is, the other end of the switch S32 is connected to the other end of the switch S21.

The switch S41 is connected between the other of the two electrodes of the capacitor C13 and the ground. In an example, one end of the switch S41 is connected to the other of the two electrodes of the capacitor C13. In an example, the other end of the switch S41 is connected to the ground.

The switch S42 is connected between the other of the two electrodes of the capacitor C13 and the node N1. In an example, one end of the switch S42 is connected to the other of the two electrodes of the capacitor C13. In an example, the other end of the switch S42 is connected to the node N1. That is, the other end of the switch S42 is connected to the other end of the switch S31.

The switch S13 is connected between one of the two electrodes of the capacitor C14 and the node N3. In an example, one end of the switch S13 is connected to one of the two electrodes of the capacitor C14. In an example, the other end of the switch S13 is connected to the node N3. That is, the other end of the switch S13 is connected to the other end of the switch S11 and the other end of the switch S22.

The switch S14 is connected between one of the two electrodes of the capacitor C14 and the node N4. In an example, one end of the switch S14 is connected to one of the two electrodes of the capacitor C14. In an example, the other end of the switch S14 is connected to the node N4. That is, the other end of the switch S14 is connected to the other end of the switch S12.

The switch S23 is an example of a fifth switch and is connected between one of the two electrodes of the capacitor C15 and the node N2. In an example, one end of the switch S23 is connected to one of the two electrodes of the capacitor C15 and the other of the two electrodes of the capacitor C14. In an example, the other end of the switch S23 is connected to the node N2. That is, the other end of the switch S23 is connected to the other end of the switch S21 and the other end of the switch S32.

The switch S24 is an example of a seventh switch and is connected between one of the two electrodes of the capacitor C15 and the node N3. In an example, one end of the switch S24 is connected to one of the two electrodes of the capacitor C15 and the other of the two electrodes of the capacitor C14. In an example, the other end of the switch S24 is connected to the node N3. That is, the other end of the switch S24 is connected to the other end of the switch S11, the other end of the switch S22, and the other end of the switch S13.

The switch S33 is an example of an eighth switch and is connected between the other of the two electrodes of the capacitor C15 and the node N1. In an example, one end of the switch S33 is connected to the other of the two electrodes of the capacitor C15 and one of the two electrodes of the capacitor C16. In an example, the other end of the switch S33 is connected to the node N1. That is, the other end of the switch S33 is connected to the other end of the switch S31 and the other end of the switch S42.

The switch S34 is an example of a sixth switch and is connected between the other of the two electrodes of the capacitor C15 and the node N2. In an example, one end of the switch S34 is connected to the other of the two electrodes of the capacitor C15 and one of the two electrodes of the capacitor C16. In an example, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. In an example, one end of the switch S43 is connected to the other of the two electrodes of the capacitor C16. In an example, the other end of the switch S43 is connected to the ground.

The switch S44 is connected between the other of the two electrodes of the capacitor C16 and the node N1. In an example, one end of the switch S44 is connected to the other of the two electrodes of the capacitor C16. In an example, the other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched ON and OFF in a complementary manner. In an example, in the first phase, the first set of switches is ON, and the second set of switches is OFF. Conversely, in the second phase, the first set of switches is OFF, and the second set of switches is ON.

For example, charging the capacitors C10 to C40 from the capacitors C11 to C13 is executed in one of the first phase and the second phase, and charging the capacitors C10 to C40 from the capacitors C14 to C16 is executed in the other of the first phase and the second phase. That is, the capacitors C10 to C40 are charged from the capacitors C11 to C13 or from the capacitors C14 to C16. Thus, even when a current flows at a high speed from the nodes N1 to N4 to the supply modulator 30, a change in potentials of the nodes N1 to N4 can be suppressed because the nodes N1 to N4 are supplemented with charges at a high speed.

The capacitors C11 to C13 are examples of a first flying capacitor. In addition, the capacitors C14 to C16 are examples of a second flying capacitor. The first flying capacitor and the second flying capacitor are a pair of flying capacitors that are charged and discharged in a complementary manner.

In an exemplary aspect, when any one of the capacitors C11 to C13 is the first flying capacitor, other one of the capacitors C11 to C13 is a third flying capacitor. The third flying capacitor is a third flying capacitor that is charged at the same timing as charging the first flying capacitor and that is discharged at the same timing as discharging the first flying capacitor.

The switched-capacitor circuit 20, by operating in the above manner, can maintain almost equal voltages at both ends of each of the capacitors C10, C20, C30, and C40. In an example, the voltages V1 to V4 (or voltages with respect to the ground potential) satisfying V1:V2:V3:V4=1:2:3:4 are maintained in four nodes labeled V1 to V4. The voltage levels of the voltages V1 to V4 correspond to the plurality of discrete voltage levels supplied to the supply modulator 30 by the switched-capacitor circuit 20.

The voltage ratio V1:V2:V3:V4 is not limited to 1:2:3:4. For example, the voltage ratio V1:V2:V3:V4 may be 1:2:4:8.

In an exemplary aspect, the configuration of the switched-capacitor circuit 20 illustrated in FIG. 3 is an example, and the present disclosure is not limited thereto. While the switched-capacitor circuit 20 is configured to supply voltages of four discrete voltage levels in FIG. 3, the switched-capacitor circuit 20 is not limited thereto. The switched-capacitor circuit 20 may be configured to supply voltages of any number of discrete voltage levels of two or more. For example, when voltages of two discrete voltage levels are supplied, the switched-capacitor circuit 20 may include at least the capacitors C12 and C15 and the switches S21, S22, S31, S32, S23, S24, S33, and S34.

### 1.2.2 Circuit Configuration of Supply Modulator 30

Still referring to FIG. 3, the circuit configuration of the supply modulator 30 can be described. As illustrated in FIG. 3, the supply modulator 30 includes input terminals 131 to 134, switches S51, S52, S53, and S54, an output terminal 130, and a control terminal 135.

In an example. the output terminal 130 is connected to the filter circuit 40. The output terminal 130 is a terminal for supplying at least one voltage selected from the voltages V1 to V4 as the power supply voltage V_{ET} to the power amplifier circuit 2 through the filter circuit 40. As described above, the supply modulator 30 may include various circuit elements and/or wires that cause a voltage drop and/or a noise and the like. Thus, the power supply voltage V_{ET} observed at the output terminal 130 may include a voltage different from the voltages V1 to V4.

In an example, the input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20.

In an example, the control terminal 135 is an input terminal of the digital control signal. That is, the control terminal 135 is a terminal for receiving the digital control signal indicating one of the voltages V1 to V4. The supply modulator 30 controls the switches S51 to S54 to be ON/OFF such that the voltage level indicated by the digital control signal is selected.

Two digital control line/logic (DCL) signals can be used as the digital control signal received through the control terminal 135. Each of the two DCL signals is a 1-bit signal. One of the voltages V1 to V4 is indicated by a combination of two 1-bit signals. For example, V1, V2, V3, and V4 are indicated by “00”, “01”, “10”, and “11”, respectively. A gray code may be used for representing the voltage level. In this case, since two DCL signals are received, two control terminals are provided. In addition, any number of one or more may be used as the number of DCL signals in accordance with the number of voltage levels. In addition, the DCL signal may be a signal of 2 bits or more. In addition, the digital control signal may be one or more DCL signals, and the control signal of the source-synchronous scheme may be used as the digital control signal.

The switch S51 is connected between the input terminal 131 and the output terminal 130. In an example, the switch S51 includes a terminal connected to the input terminal 131 and a terminal connected to the output terminal 130. In this connection configuration, the switch S51 can be switched ON/OFF to switch between a connected state and a non-connected state between the input terminal 131 and the output terminal 130.

The switch S52 is an example of a tenth switch and is connected between the input terminal 132 and the output terminal 130. In an example, the switch S52 includes a terminal connected to the input terminal 132 and a terminal connected to the output terminal 130. In this connection configuration, the switch S52 can be switched ON/OFF to switch between a connected state and a non-connected state between the input terminal 132 and the output terminal 130.

The switch S53 is an example of a ninth switch and is connected between the input terminal 133 and the output terminal 130. In an example, the switch S53 includes a terminal connected to the input terminal 133 and a terminal connected to the output terminal 130. In this connection configuration, the switch S53 can be switched ON/OFF to switch between a connected state and a non-connected state between the input terminal 133 and the output terminal 130.

In an exemplary aspect, the switch S54 is connected between the input terminal 134 and the output terminal 130. In an example, the switch S54 includes a terminal connected to the input terminal 134 and a terminal connected to the output terminal 130. In this connection configuration, the switch S54 can be switched ON/OFF to switch between a connected state and a non-connected state between the input terminal 134 and the output terminal 130.

The switches S51 to S54 are controlled to be exclusively ON. That is, only one of the switches S51 to S54 is ON, and the rest of the switches S51 to S54 is OFF. Accordingly, the supply modulator 30 can output one voltage selected from the voltages V1 to V4.

The configuration of the supply modulator 30 illustrated in FIG. 3 is an example, and the present disclosure is not limited thereto. In an aspect, the switches S51 to S54 may have any configurations as long as any of the four input terminals 131 to 134 can be selected and connected to the output terminal 130. For example, the supply modulator 30 may further include a switch connected between the switches S51 to S53, and the switch S54 and the output terminal 130. In an exemplary aspect, the supply modulator 30 may further include a switch connected between the switches S51 and S52, and the switches S53 and S54 and the output terminal 130.

In an example, in the case of selecting one voltage from the second voltages of two discrete voltage levels, the supply modulator 30 may include at least the switches S52 and S53.

In an example, the supply modulator 30 may be configured to output two or more voltages. In this case, the supply modulator 30 may further include a necessary number of additional switch sets like the set of switches S51 to S54 and a necessary number of additional output terminals.

### 1.2.3 Circuit Configuration of Pre-Regulator Circuit 10

Still referring to FIG. 3, the circuit configuration of the pre-regulator circuit 10 can be described. As illustrated in FIG. 3, the pre-regulator circuit 10 includes an input terminal 110, output terminals 111 to 114, inductor connection terminals 115 and 116, a control terminal 117, switches S61, S62, S63, S71, and S72, a power inductor L71, and capacitors C61, C62, C63, and C64.

The input terminal 110 is an example of a third input terminal and is an input terminal of a direct current voltage. That is, the input terminal 110 is a terminal for receiving the input voltage from the direct current power source 50.

In an exemplary aspect, the output terminal 111 is an output terminal of the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal of the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal of the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal of the voltage V1. That is, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The control terminal 117 is an input terminal of the digital control signal. That is, the control terminal 117 is a terminal for receiving the digital control signal for controlling the pre-regulator circuit 10.

The switch S71 is an example of an eleventh switch and is connected between the input terminal 110 and one end of the power inductor L71. In an example, the switch S71 includes a terminal connected to the input terminal 110 and a terminal connected to one end of the power inductor L71 through the inductor connection terminal 115. In this connection configuration, the switch S71 can be switched ON/OFF to switch between a connected state and a non-connected state between the input terminal 110 and one end of the power inductor L71.

The switch S72 is an example of a twelfth switch and is connected between one end of the power inductor L71 and the ground. In an example, the switch S72 includes a terminal connected to one end of the power inductor L71 through the inductor connection terminal 115 and a terminal connected to the ground. In this connection configuration, the switch S72 can be switched ON/OFF to switch between a connected state and a non-connected state between one end of the power inductor L71 and the ground.

The switch S61 is connected between the other end of the power inductor L71 and the output terminal 111. In an example, the switch S61 includes a terminal connected to the other end of the power inductor L71 and a terminal connected to the output terminal 111. In this connection configuration, the switch S61 can be switched ON/OFF to switch between a connected state and a non-connected state between the other end of the power inductor L71 and the output terminal 111.

The switch S62 is connected between the other end of the power inductor L71 and the output terminal 112. In an example, the switch S62 includes a terminal connected to the other end of the power inductor L71 and a terminal connected to the output terminal 112. In this connection configuration, the switch S62 can be switched ON/OFF to switch between a connected state and a non-connected state between the other end of the power inductor L71 and the output terminal 112.

The switch S63 is connected between the other end of the power inductor L71 and the output terminal 113. In an example, the switch S63 includes a terminal connected to the other end of the power inductor L71 and a terminal connected to the output terminal 113. In this connection configuration, the switch S63 can be switched ON/OFF to switch between a connected state and a non-connected state between the other end of the power inductor L71 and the output terminal 113.

The capacitor C61 is connected between the output terminal 111 and the output terminal 112. One of two electrodes of the capacitor C61 is connected to the switch S61 and the output terminal 111, and the other of the two electrodes of the capacitor C61 is connected to the switch S62, the output terminal 112, and one of two electrodes of the capacitor C62.

The capacitor C62 is connected between the output terminal 112 and the output terminal 113. One of the two electrodes of the capacitor C62 is connected to the switch S62, the output terminal 112, and the other of the two electrodes of the capacitor C61, and the other of the two electrodes of the capacitor C62 is connected to a path connecting the switch S63, the output terminal 113, and one of two electrodes of the capacitor C63.

The capacitor C63 is an example of a fourth capacitor and is connected between the output terminal 113 and the output terminal 114. One of two electrodes of the capacitor C63 is connected to the switch S63, the output terminal 113, and the other of the two electrodes of the capacitor C62, and the other of the two electrodes of the capacitor C63 is connected to the output terminal 114 and one of two electrodes of the capacitor C64.

The capacitor C64 is connected between the output terminal 114 and the ground. One of the two electrodes of the capacitor C64 is connected to the output terminal 114 and the other of the two electrodes of the capacitor C63, and the other of the two electrodes of the capacitor C64 is connected to the ground.

The switches S61 to S63 are controlled to be exclusively ON. That is, only one of the switches S61 to S63 is ON, and the rest of the switches S61 to S63 is OFF. By causing only one of the switches S61 to S63 to be ON, the pre-regulator circuit 10 can change the voltage to be supplied to the switched-capacitor circuit 20 among the voltage levels of the voltages V2 to V4.

The pre-regulator circuit 10 configured in the above manner supplies charges to the switched-capacitor circuit 20 through at least one of the output terminals 111 to 113.

In the case of converting the input voltage (third voltage) into one first voltage, the pre-regulator circuit 10 may include at least the switches S71 and S72 and the power inductor L71.

### 1.2.4 Circuit Configuration of Filter Circuit 40

Still referring to FIG. 3, the circuit configuration of the filter circuit 40 can be described. As illustrated in FIG. 3, the filter circuit 40 includes inductors L51, L52, and L53, capacitors C51 and C52, a resistor R51, an input terminal 140, and an output terminal 141.

The input terminal 140 is an input terminal of the second voltage selected by the supply modulator 30. That is, the input terminal 140 is a terminal for receiving the second voltage selected from the plurality of voltages V1 to V4.

The output terminal 141 is an output terminal of the power supply voltage V_{ET}. That is, the output terminal 141 is a terminal for supplying the power supply voltage V_{ET} to the power amplifier circuit 2.

The inductor L51 and the inductor L52 are connected in series to each other between the input terminal 140 and the output terminal 141. A series connection circuit of the inductor L53 and the resistor R51 is connected in parallel to the inductor L51. The capacitor C51 is connected between a connection point between the inductors L51 and L52 and the ground. The capacitor C52 is connected between the output terminal 141 and the ground.

In the above configuration, the filter circuit 40 forms an LC low pass filter in which an inductor is disposed on a series arm path and a capacitor is disposed on a parallel arm path. Accordingly, the filter circuit 40 can reduce a radio frequency component included in the power supply voltage. For example, when the predetermined band is a frequency band for frequency division duplex (FDD), the filter circuit 40 is configured to reduce a component of a downlink operation band of the predetermined band.

It should be noted that the configuration of the filter circuit 40 illustrated in FIG. 3 is an example, and the present disclosure is not limited thereto. The filter circuit 40 can form a band pass filter or a high pass filter depending on a band to be removed.

In an exemplary aspect, the filter circuit 40 may include two or more LC filters. The two or more LC filters may be connected in common to the output terminal 130, and each LC filter may have a passband or an attenuation band corresponding to each of different bands. In an exemplary aspect, a first filter group configured with two or more LC filters may be connected to a first output terminal of the supply modulator 30, a second filter group configured with another two or more LC filters may be connected to a second output terminal of the supply modulator 30, and each LC filter may have a passband or an attenuation band corresponding to each of different bands. In this case, the filter circuit 40 may include two or more output terminals and output two or more power supply voltages V_{ET} to the power amplifier circuit 2 at the same time.

In an example, in the case of configuring the tracker module by mounting each switch of the switched-capacitor circuit 20 and the supply modulator 30 on the module laminate as a switch integrated circuit of one chip, large currents with large voltage changes that are caused by high-speed charging and discharging of the capacitors can flow through a plurality of wires which connects the switches and the capacitors of the switched-capacitor circuit 20. Thus, large electromagnetic field noise may be generated because of interference between signals flowing among the plurality of wires.

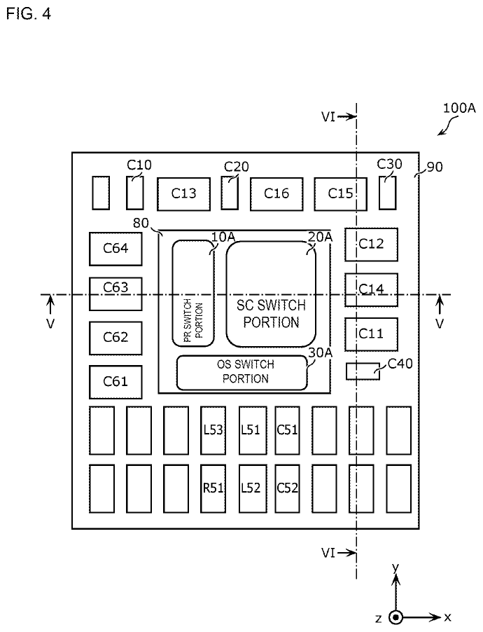

In an exemplary aspect, a configuration for suppressing electromagnetic field noise generated by interference between signals flowing among the plurality of wires in the tracker module on which the power supply circuit 1 according to the present embodiment is mounted can be described in FIGS. 4-6.

### 2 Disposition Configuration of Components of Tracker Module 100A According to Example 1

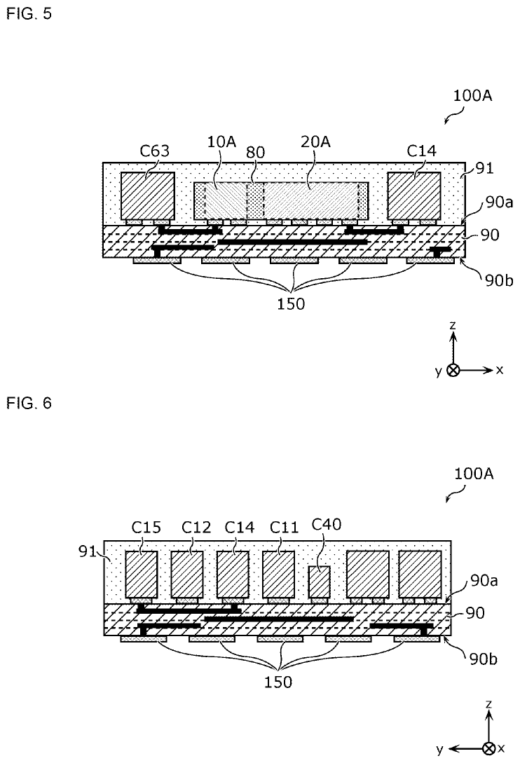

FIG. 4 is a plan view of a tracker module 100A according to Example 1. FIG. 5 is a first cross-sectional view of the tracker module 100A according to Example 1 and specifically, is a cross-sectional view taken along line V-V in FIG. 4. FIG. 6 is a second cross-sectional view of the tracker module 100A according to Example 1 and specifically, is a cross-sectional view taken along line VI-VI in FIG. 4. FIG. 4 illustrates a diagram of disposition of circuit components in a case where a main surface 90a out of main surfaces 90a and 90b of a module laminate 90 facing each other is viewed from a side in the positive direction of the z-axis.

The tracker module 100A according to the present example illustrates a disposition configuration of a part of each circuit component forming the power supply circuit 1 according to the exemplary embodiment in FIG. 4.

As illustrated in FIGS. 4 to 6, the tracker module 100A according to the present example includes the module laminate 90, an integrated circuit 80, the capacitors C10, C20, C30, C40, C11, C12, C13, C14, C15, C16, C51, C52, C61, C62, C63, and C64, the inductors L51, L52, and L53, the resistor R51, and a resin member 91.

The module laminate 90 has the main surface 90a and the main surface 90b facing each other and is a laminate on which the circuit components forming the tracker module 100A are mounted. For example, a low temperature co-fired ceramics (LTCC) laminate, a high temperature co-fired ceramics (HTCC) laminate, a component-embedded board, a laminate having a redistribution layer (RDL), or a printed circuit board having a laminated structure of a plurality of dielectric layers is used as the module laminate 90.

The integrated circuit 80 is a semiconductor integrated circuit (IC). For example, the integrated circuit 80 is configured using a complementary metal oxide semiconductor (CMOS) and is manufactured through a silicon on insulator (SOI) process. The integrated circuit 80 may be formed of at least one of GaAs, SiGe, or GaN. A semiconductor material of the integrated circuit 80 is not limited to the above materials.

The integrated circuit 80 includes a PR switch portion 10A, an SC switch portion 20A, and an OS switch portion 30A.

The PR switch portion 10A is configured with switches included in the pre-regulator circuit 10. Specifically, the PR switch portion 10A includes the switches S61, S62, S63, S71, and S72.

The SC switch portion 20A is configured with switches included in the switched-capacitor circuit 20. In an example, the SC switch portion 20A includes the switches S11, S12, S13, S14, S21, S22, S23, S24, S31, S32, S33, S34, S41, S42, S43, and S44.

The OS switch portion 30A is configured with switches included in the supply modulator 30. Specifically, the OS switch portion 30A includes the switches S51, S52, S53, and S54.

The capacitors C10, C20, C30, C40, C11, C12, C13, C14, C15, and C16 are capacitors included in the switched-capacitor circuit 20. In an example, the capacitors C51 and C52 are capacitors included in the filter circuit 40. In an example, the capacitors C61, C62, C63, and C64 are capacitors included in the pre-regulator circuit 10.

A plurality of input-output electrodes is formed on a surface of the integrated circuit 80 facing the main surface 90a. The plurality of input-output electrodes is electrically connected to a plurality of circuit components disposed on the main surface 90a, a plurality of external connection electrodes 150 disposed on the main surface 90b, or the like through a wire layer, a via conductor, or the like formed in the module laminate 90.

In an exemplary aspect, at least one of the plurality of input-output electrodes is connected to the RFIC 5 disposed outside the tracker module 100A through the external connection electrode 150 (or a control terminal 135).

The resin member 91 is disposed on the main surface 90a and covers the main surface 90a and a part of the circuit components forming the tracker module 100A. The resin member 91 has a function of securing reliability such as mechanical strength and humidity resistance of the circuit components forming the tracker module 100A. In an aspect, the resin member 91 may not be an essential component to the tracker module 100A according to the present example.

The tracker module 100A may include the capacitors C11, C12, and C14 among the capacitors included in the switched-capacitor circuit 20 among the capacitors C10 to C64. In addition, the integrated circuit 80 may include the SC switch portion 20A and the OS switch portion 30A. Furthermore, the SC switch portion 20A may include at least one of the switches S11 to S44, and the OS switch portion 30A may include at least one of the switches S51 to S54.

In an exemplary aspect, the integrated circuit 80 may include the SC switch portion 20A and the OS switch portion 30A, and an integrated circuit different from the integrated circuit 80 may include the PR switch portion 10A. In this case, only the integrated circuit 80 out of the two integrated circuits may be disposed on the module laminate 90, or the two integrated circuits may be disposed on the module laminate 90.

In an exemplary aspect, the external connection electrodes 150 are disposed on the main surface 90b. The tracker module 100A exchanges electric signals with the RFIC 5, the power amplifier circuit 2, and an external laminate disposed on a side of the tracker module 100A in the negative direction of the z-axis through the plurality of external connection electrodes 150. In an example, some of the plurality of external connection electrodes 150 are set to have the ground potential.

The external connection electrodes 150 may be a planar electrode as illustrated in FIGS. 5 and 6 or may be bump electrodes formed on the main surface 90b.

In an exemplary aspect, while illustration is not provided in FIG. 4, wires connecting each circuit component illustrated in FIG. 3 are formed inside the module laminate 90 and on the main surfaces 90a and 90b. In an exemplary aspect, the wires may be bonding wires of which both ends are joined to any of the main surfaces 90a and 90b and the circuit components or may be terminals, electrodes, or wires formed on the surfaces of the circuit components.

In the tracker module 100A, as illustrated in FIGS. 4 and 6, the capacitor C14 is disposed between the capacitor C11 and the capacitor C12. In the present example, the capacitor C11 and the capacitor C14 are examples of the first flying capacitor and the second flying capacitor, respectively, that are charged and discharged in a complementary manner. In addition, the capacitor C12 is an example of the third flying capacitor that is charged at the same timing as charging of the capacitor C11 and that is discharged at the same timing as discharging of the capacitor C11.

In the switched-capacitor circuit 20, by applying the digital ET, charging and discharging the flying capacitors are repeated at a high speed. Thus, large currents having rapid voltage changes can flow through wires that connect the flying capacitors to the switches. Thus, when wires connected to two flying capacitors executing charging (and discharging) at the same time are close to each other, large electromagnetic field noise may be generated by interference between signals flowing between the wires.

In an exemplary aspect, according to the above configuration, the second flying capacitor that executes charging and discharging in a complementary manner to the two flying capacitors (e.g., the first flying capacitor and the third flying capacitor) executing charging (or discharging) at the same time is disposed between the two flying capacitors. Accordingly, a long distance can be secured between a wire connecting the integrated circuit 80 to the first flying capacitor and a wire connecting the integrated circuit 80 to the third flying capacitor. In an exemplary aspect, a wire through which a signal having a different phase from signals flowing through the two wires is interposed between the two wires. Thus, since interference between the signals flowing between the two wires can be suppressed, electromagnetic field noise generated by the interference can be suppressed.

In an exemplary aspect, the expression “a wire through which a signal having a different phase from signals flowing through the two wires is interposed between the two wires” means that a wire to which the second flying capacitor that executes charging and discharging in a complementary manner to the first flying capacitor and the third flying capacitor to which the two wires are connected is connected is interposed between the two wires.

The present disclosure is not limited to disposition of the capacitor C14 between the capacitor C11 and the capacitor C12. In an example, at least one of the capacitors C14 to C16 may be disposed between two of the capacitors C11 to C13, and at least one of the capacitors C11 to C13 may be disposed between two of the capacitors C14 to C16. That is, a flying capacitor that executes charging and discharging in a complementary manner to two flying capacitors executing charging (discharging) at the same time may be disposed between the two flying capacitors.

In an example, the capacitors C11 and C14 are capacitors to which the highest potential (e.g., voltage V4) is applied among the plurality of capacitors included in the switched-capacitor circuit 20. Thus, the wire connected to the capacitor C11 has the largest amount of charge movement. In an example, by securing a long distance between the wire connected to the capacitor C11 and the wire connected to the capacitor C12 or C13 executing charging (or discharging) at the same time as the capacitor C11, electromagnetic field noise generated by interference between signals flowing between the two wires can be effectively suppressed.

In an exemplary aspect, a potential of the capacitor C14 disposed between the capacitor C11 and the capacitor C12 at charging is equal to a potential of the capacitor C11 at charging.

Accordingly, an electromagnetic field generated by a wire connecting the integrated circuit 80 to the capacitor C11 can be canceled out with high accuracy by an electromagnetic field generated by a wire that connects the integrated circuit 80 to the second flying capacitor and through which a signal having an opposite phase to a signal flowing through the wire connecting the integrated circuit 80 to the first flying capacitor flows. Thus, interference between signals flowing through the wire connecting the integrated circuit 80 to the first flying capacitor and the wire connecting the integrated circuit 80 to the third flying capacitor can be suppressed with high accuracy.

In an exemplary aspect, in the tracker module 100A, each of the capacitors C11, C12, and C14 is adjacent to the integrated circuit 80.

In an example, the integrated circuit 80 being adjacent to the capacitor C11 means that the integrated circuit 80 is disposed close to the capacitor C11 and specifically, a circuit component is not present in a space interposed between a side surface of the integrated circuit 80 and a side surface of the capacitor C11 facing each other. The circuit component includes active components such as a transistor and a diode and passive components such as an inductor, a transformer, a capacitor, and a resistor and does not include a terminal, a connector, an electrode, a wire, a resin member, and the like.

In the switched-capacitor circuit 20, the plurality of high-accuracy and stable second voltages can be supplied to the supply modulator 30 by repeating charging and discharging of the capacitors. Thus, it is desirable that charges can move through wires connecting the capacitors to the switches connected to the capacitors at a high speed with low resistance.

In an exemplary aspect, since the integrated circuit 80 is adjacent to the capacitors of the switched-capacitor circuit 20, wires connecting the capacitors to the switches of the SC switch portion 20A can be shortened. Thus, parasitic resistance and parasitic inductance of the wires in the switched-capacitor circuit 20 can be decreased. Thus, electromagnetic field noise generated by interference among a plurality of adjacent wires can be suppressed. In an exemplary aspect, since the plurality of high-accuracy and stable second voltages can be supplied to the supply modulator 30 from the switched-capacitor circuit 20, deterioration of the output waveform of the power supply voltage V_{ET} output from the tracker module 100A can be suppressed.

In an example, each of the capacitors C11, C12, and C14 is adjacent to the SC switch portion 20A of the integrated circuit 80.

Accordingly, wires connecting each of the capacitors C11, C12, and C14 to the switches of the SC switch portion 20A can be further shortened. Thus, electromagnetic field noise generated by interference among a plurality of adjacent wires can be suppressed.

### 3 Disposition Configuration of Components of Tracker Module 100B According to Example 2

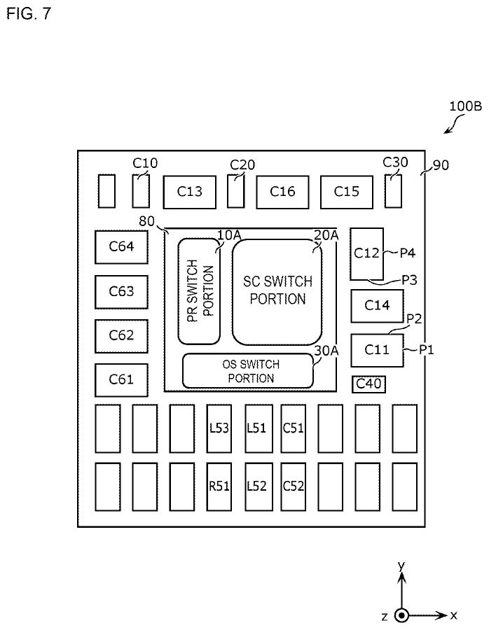

FIG. 7 is a plan view of a tracker module 100B according to Example 2. FIG. 7 illustrates a diagram of disposition of circuit components in a case where the main surface 90a out of the main surfaces 90a and 90b of the module laminate 90 facing each other is viewed from the side in the positive direction of the z-axis.

The tracker module 100B according to the present example illustrates a disposition configuration of a part of each circuit component forming the power supply circuit 1 according to the exemplary embodiment in FIG. 7.

As illustrated in FIG. 7, the tracker module 100B according to the present example includes the module laminate 90, the integrated circuit 80, the capacitors C10, C20, C30, C40, C11, C12, C13, C14, C15, C16, C51, C52, C61, C62, C63, and C64, the inductors L51, L52, and L53, the resistor R51, and the resin member 91 (not illustrated). The tracker module 100B according to the present example has a different disposition configuration of the capacitor C12 from the tracker module 100A according to Example 1. Hereinafter, in the tracker module 100B according to the present example, the same configurations as the tracker module 100A according to Example 1 will not be described, and only different configurations will be mainly described.

In the tracker module 100B, as illustrated in FIG. 7, the capacitor C14 is disposed between the capacitor C11 and the capacitor C12. In an example shown in FIG. 7, the capacitor C11 and the capacitor C14 are examples of the first flying capacitor and the second flying capacitor, respectively, that are charged and discharged in a complementary manner. In addition, the capacitor C12 is an example of the third flying capacitor that is charged at the same timing as charging of the capacitor C11 and that is discharged at the same timing as discharging of the capacitor C11.

According to the above configuration, the second flying capacitor that executes charging and discharging in a complementary manner to the two flying capacitors (e.g., the first flying capacitor and the third flying capacitor) executing charging (or discharging) at the same time is disposed between the two flying capacitors. Accordingly, a long distance can be secured between the wire connecting the integrated circuit 80 to the first flying capacitor and the wire connecting the integrated circuit 80 to the third flying capacitor. In addition, a wire through which a signal having a different phase from the signals flowing through the two wires is interposed between the two wires. Thus, since interference between the signals flowing between the two wires can be suppressed, electromagnetic field noise generated by the interference can be suppressed.

The present disclosure is not limited to disposition of the capacitor C14 between the capacitor C11 and the capacitor C12. At least one of the capacitors C14 to C16 may be disposed between two of the capacitors C11 to C13, and at least one of the capacitors C11 to C13 may be disposed between two of the capacitors C14 to C16. That is, a flying capacitor that executes charging and discharging in a complementary manner to two flying capacitors executing charging (or discharging) at the same time may be disposed between the two flying capacitors.

In an exemplary aspect, in the plan view of the module laminate 90, the capacitor C11 has a rectangular shape having a short edge P1 and a long edge P2, and the capacitor C12 has a rectangular shape having a short edge P3 and a long edge P4. Here, the long edge P2 of the capacitor C11 intersects the long edge P4 of the capacitor C12.

In the plan view of the module laminate 90, intersection between two edges means that the two edges are not parallel in the plan view.

Accordingly, since a direction of an electromagnetic field generated in the capacitor C11 intersects a direction of an electromagnetic field generated in the capacitor C12, reinforcement of interference between the two electromagnetic fields can be suppressed. Thus, electromagnetic field noise generated by interference between the electromagnetic fields generated in the capacitor C11 and the capacitor C12 can be suppressed.

In an example, the long edge P2 of the capacitor C11 is orthogonal to the long edge P4 of the capacitor C12. Accordingly, since the direction of the electromagnetic field generated in the capacitor C11 is orthogonal to the direction of the electromagnetic field generated in the capacitor C12, reinforcement of interference between the two electromagnetic fields can be avoided.

A direction of the electromagnetic field generated in the capacitor C11 with respect to the long edge P2 is desirably equal to a direction of the electromagnetic field generated in the capacitor C12 with respect to the long edge P4. Accordingly, since the long edge P2 of the capacitor C11 intersects the long edge P4 of the capacitor C12, the electromagnetic field noise can be effectively suppressed.

### 4 Disposition Configuration of Components of Tracker Module 100C According to Example 3

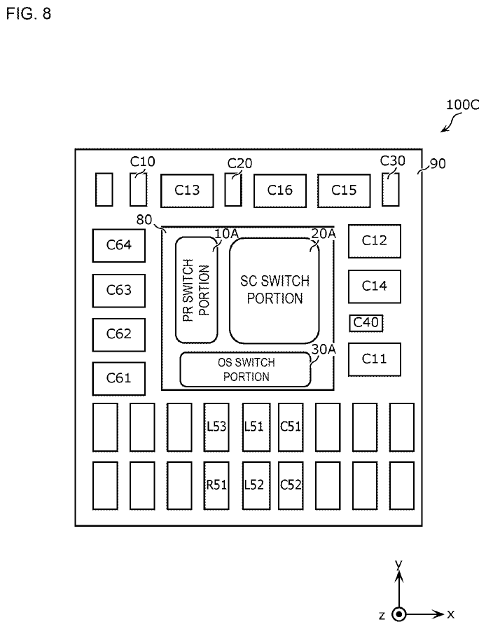

FIG. 8 is a plan view of a tracker module 100C according to Example 3. FIG. 8 illustrates a diagram of disposition of circuit components in a case where the main surface 90a out of the main surfaces 90a and 90b of the module laminate 90 facing each other is viewed from the side in the positive direction of the z-axis.

The tracker module 100C illustrates an exemplary disposition configuration of a part of each circuit component forming the power supply circuit 1 according to the embodiment shown in FIG. 8.

As illustrated in FIG. 8, the tracker module 100C according to the present example includes the module laminate 90, the integrated circuit 80, the capacitors C10, C20, C30, C40, C11, C12, C13, C14, C15, C16, C51, C52, C61, C62, C63, and C64, the inductors L51, L52, and L53, the resistor R51, and the resin member 91 (not illustrated). The tracker module 100C according to the present example has a different disposition configuration of the capacitor C40 from the tracker module 100A according to Example 1. Hereinafter, in the tracker module 100C according to the present example, the same configurations as the tracker module 100A according to Example 1 will not be described, and only different configurations will be mainly described.

In the tracker module 100C, as illustrated in FIG. 8, the capacitor C14 is disposed between the capacitor C11 and the capacitor C12. In an aspect of the disclosure in FIG. 8, the capacitor C11 and the capacitor C14 are examples of the first flying capacitor and the second flying capacitor, respectively, that are charged and discharged in a complementary manner. In an aspect of the disclosure in FIG. 8, the capacitor C12 is an example of the third flying capacitor that is charged at the same timing as charging of the capacitor C11 and that is discharged at the same timing as discharging of the capacitor C11.

According to the above configuration, the second flying capacitor that executes charging and discharging in a complementary manner to the two flying capacitors (e.g., the first flying capacitor and the third flying capacitor) executing charging (or discharging) at the same time is disposed between the two flying capacitors. Accordingly, a long distance can be secured between the wire connecting the integrated circuit 80 to the first flying capacitor and the wire connecting the integrated circuit 80 to the second flying capacitor. In addition, a wire through which a signal having a different phase from the signals flowing through the two wires is interposed between the two wires. Thus, since interference between the signals flowing between the two wires can be suppressed, electromagnetic field noise generated by the interference can be suppressed.

The present disclosure is not limited to disposition of the capacitor C14 between the capacitor C11 and the capacitor C12. At least one of the capacitors C14 to C16 may be disposed between two of the capacitors C11 to C13, and at least one of the capacitors C11 to C13 may be disposed between two of the capacitors C14 to C16. That is, a flying capacitor that executes charging and discharging in a complementary manner to two flying capacitors executing charging (or discharging) at the same time may be disposed between the two flying capacitors.

In an exemplary aspect, in the tracker module 100C, the capacitor C40 is disposed between the capacitor C11 and the capacitor C12. The capacitor C40 is a smoothing capacitor that is connected between the capacitor C11 and the capacitor C14 and that smooths voltages of the capacitors C11 and C14.

According to this configuration, the smoothing capacitor that does not execute charging and discharging at the same timing as the two flying capacitors (e.g., the first flying capacitor and the third flying capacitor) executing charging (or discharging) at the same time is disposed between the two flying capacitors. Accordingly, a further long distance can be secured between the wire connecting the integrated circuit 80 to the first flying capacitor and the wire connecting the integrated circuit 80 to the third flying capacitor. In addition, a wire through which a signal having a different phase from the signals flowing through the two wires is interposed between the two wires. Thus, since interference between the signals flowing between the two wires can be further suppressed, electromagnetic field noise generated by the interference can be further suppressed.

The present disclosure is not limited to disposition of the capacitor C40 between the capacitor C11 and the capacitor C12. The capacitor C30 may be disposed between the capacitor C11 and the capacitor C12.

In an exemplary aspect, at least one of the capacitors C10, C20, C30, and C40 may be disposed between two of the capacitors C11, C12, and C13. In an exemplary aspect, at least one of the capacitors C10, C20, C30, and C40 may be disposed between two of the capacitors C14, C15, and C16.

### 5 Effects

As described above, the tracker modules 100A, 100B, and 100C according to Examples 1 to 3 include the module laminate 90, the integrated circuit 80 disposed on the module laminate 90, and a plurality of capacitors that are disposed on the module laminate 90 and that are included in the switched-capacitor circuit 20 configured to generate the plurality of discrete voltages based on the input voltage. The integrated circuit 80 includes a switch included in the switched-capacitor circuit 20 and a switch included in the supply modulator 30 configured to selectively output at least one of the plurality of discrete voltages generated by the switched-capacitor circuit 20. The plurality of capacitors includes the first flying capacitor and the second flying capacitor that are charged and discharged in a complementary manner, and the third flying capacitor that is charged at the same timing as charging of the first flying capacitor and that is discharged at the same timing as discharging of the first flying capacitor. The second flying capacitor is disposed between the first flying capacitor and the third flying capacitor.

In the switched-capacitor circuit 20, by applying the digital ET, charging and discharging the flying capacitors are repeated at a high speed. Thus, large currents having rapid voltage changes flow through the wires connecting the flying capacitors to the switches. Thus, particularly, when wires connected to two flying capacitors executing charging (and/or discharging) at the same time are close to each other, large electromagnetic field noise may be generated by interference between signals flowing between the wires.

In an exemplary aspect, according to the above configuration, the second flying capacitor that executes charging and discharging in a complementary manner to the two flying capacitors (e.g., the first flying capacitor and the third flying capacitor) executing charging (or discharging) at the same time is disposed between the two flying capacitors. Accordingly, for example, even within a limited region, a distance can be secured between the wire connecting the integrated circuit 80 to the first flying capacitor and the wire connecting the integrated circuit 80 to the third flying capacitor. In addition, a wire through which a signal having a different phase from the signals flowing through the two wires is interposed between the two wires. Thus, since interference between the signals flowing between the two wires can be suppressed, electromagnetic field noise generated by the interference can be suppressed.

In an exemplary aspect, in the tracker modules 100A, 100B, and 100C, the supply modulator 30 may be configured to control the output voltage based on the envelope signal of the radio frequency signal.

According to this configuration, the digital ET mode can be applied to the power amplifier circuit 2, and electromagnetic field noise generated by interference between the signals flowing between the two wires can be suppressed.

In addition, for example, in the tracker module 100B, in the plan view of the module laminate 90, each of the capacitor C11 (or first flying capacitor) and the capacitor C12 (or third flying capacitor) may have a rectangular shape having a short edge and a long edge, and the long edge P2 of the capacitor C11 may intersect the long edge P4 of the capacitor C12.

According to this configuration, since the direction of the electromagnetic field generated in the capacitor C11 intersects the direction of the electromagnetic field generated in the capacitor C12, reinforcement of interference between the two electromagnetic fields can be suppressed. Thus, electromagnetic field noise generated by interference between the electromagnetic fields generated in the capacitor C11 and the capacitor C12 can be suppressed.

In an exemplary aspect, in the tracker module 100C, the plurality of capacitors may further include the capacitor C40 that is connected between the capacitor C11 (or first flying capacitor) and the capacitor C12 (or second flying capacitor) and that is configured to smooth the voltages of the capacitors C11 and C14, and the capacitor C40 may be disposed between the capacitor C11 and the capacitor C12.

According to this configuration, the smoothing capacitor that does not execute charging and discharging at the same timing as the two flying capacitors (e.g., the first flying capacitor and the third flying capacitor) executing charging (or discharging) at the same time is disposed between the two flying capacitors. Accordingly, a further long distance can be secured between the wire connecting the integrated circuit 80 to the first flying capacitor and the wire connecting the integrated circuit 80 to the third flying capacitor. In addition, a wire through which a signal having a different phase from the signals flowing through the two wires is interposed between the two wires. Thus, since interference between the signals flowing between the two wires can be further suppressed, electromagnetic field noise generated by the interference can be further suppressed.

In an exemplary aspect, in the tracker modules 100A, 100B, and 100C, a potential difference between a potential of the second flying capacitor at charging and a potential of the first flying capacitor at charging may be the smallest of potential differences between the potential of the second flying capacitor at charging and potentials of flying capacitors other than the second flying capacitor at charging.

According to this configuration, the electromagnetic field generated by the wire connecting the integrated circuit 80 to the first flying capacitor can be canceled out with high accuracy by the electromagnetic field generated by the wire that connects the integrated circuit 80 to the second flying capacitor and through which a signal having an opposite phase to and the same amplitude as the signal flowing through the wire connecting the integrated circuit 80 to the first flying capacitor flows. Thus, interference between signals flowing through the wire connecting the integrated circuit 80 to the first flying capacitor and the wire connecting the integrated circuit 80 to the third flying capacitor can be suppressed with high accuracy.

In an exemplary aspect, for example, in the tracker modules 100A, 100B, and 100C, the first flying capacitor may be a capacitor to which the highest potential is applied among the plurality of capacitors included in the switched-capacitor circuit 20.

According to this configuration, the wire connected to the first flying capacitor has the largest amount of charge movement. Meanwhile, by securing a long distance between the wire connected to the first flying capacitor and the wire connected to the third flying capacitor, electromagnetic field noise generated by interference between the signals flowing between the two wires can be effectively suppressed.

In an exemplary aspect, in the tracker modules 100A, 100B, and 100C, each of the first flying capacitor, the second flying capacitor, and the third flying capacitor may be adjacent to the integrated circuit 80.

According to this configuration, since the integrated circuit 80 is adjacent to the capacitors of the switched-capacitor circuit 20, the wires connecting the capacitors to the switches of the SC switch portion 20A can be shortened. Thus, parasitic resistance and parasitic inductance of the wires in the switched-capacitor circuit 20 can be decreased. Thus, electromagnetic field noise generated by interference among a plurality of adjacent wires can be suppressed. In an exemplary aspect, since the plurality of high-accuracy and stable second voltages can be supplied to the supply modulator 30 from the switched-capacitor circuit 20, deterioration of the output waveform of the power supply voltage V_{ET} output from the tracker module can be suppressed.

In an exemplary aspect, the tracker modules 100A, 100B, and 100C according to Examples 1 to 3 include the module laminate 90, the first circuit, and the second circuit. The first circuit includes the first capacitor including the first electrode and the second electrode, the second capacitor including the third electrode and the fourth electrode, the third capacitor including the fifth electrode and the sixth electrode, and the switches S21, S32, S22, S31, S23, S34, S24, and S33. One end of the switch S21 and one end of the switch S22 are connected (or coupled) to the first electrode. One end of the switch S32 and one end of the switch S31 are connected to the second electrode and the fifth electrode. One end of the switch S23 and one end of the switch S24 are connected to the third electrode. One end of the switch S34 and one end of the switch S33 are connected to the fourth electrode. The other end of the switch S21, the other end of the switch S32, the other end of the switch S23, and the other end of the switch S34 are connected to each other. The other end of the switch S22 is connected to the other end of the switch S24. The other end of the switch S31 is connected to the other end of the switch S33. The second circuit includes the output terminal 130, the switch S53 connected between the output terminal 130 and the other end of the switch S21, the other end of the switch S32, the other end of the switch S23, and the other end of the switch S34, and the switch S52 connected between the output terminal 130 and the other end of the switch S22 and the other end of the switch S24. The switches S21, S22, S23, S24, S31, S32, S33, S34, S52, and S53 are included in the integrated circuit 80. The first capacitor, the second capacitor, the third capacitor, and the integrated circuit 80 are disposed on the module laminate 90. The second capacitor is disposed between the first capacitor and the third capacitor.

According to this configuration, the second capacitor that executes charging and discharging in a complementary manner to the two capacitors of the first capacitor and the third capacitor executing charging (or discharging) at the same time is disposed between the two capacitors. Accordingly, a long distance can be secured between a wire connecting the integrated circuit 80 to the first capacitor and a wire connecting the integrated circuit 80 to the third capacitor. In addition, a wire through which a signal having a different phase from signals flowing through the two wires is interposed between the two wires. Thus, since interference between the signals flowing between the two wires can be suppressed, electromagnetic field noise generated by the interference can be suppressed.

In an exemplary aspect, in the tracker module 100B, in the plan view of the module laminate 90, each of the first capacitor and the third capacitor may have a rectangular shape having a short edge and a long edge, and the long edge of the first capacitor may intersect the long edge of the third capacitor.

According to this configuration, since a direction of an electromagnetic field generated in the first capacitor intersects a direction of an electromagnetic field generated in the third capacitor, reinforcement of interference between the two electromagnetic fields can be suppressed. Thus, electromagnetic field noise generated by interference between the electromagnetic fields generated in the first capacitor and the third capacitor can be suppressed.

In an exemplary aspect, in the tracker module 100C, the first circuit may further include the fourth capacitor including the seventh electrode and the eighth electrode. The seventh electrode may be connected to the other end of the switch S21, the other end of the switch S32, the other end of the switch S23, and the other end of the switch S34. The eighth electrode may be connected to the other end of the switch S22 and the other end of the switch S24 or connected to the other end of the switch S31 and the other end of the switch S33. The fourth capacitor may be disposed between the first capacitor and the third capacitor.

According to this configuration, the fourth capacitor that does not execute charging and discharging at the same timing as the first capacitor and the third capacitor executing charging (or discharging) at the same time is disposed between the two capacitors. Accordingly, a further long distance can be secured between the wire connecting the integrated circuit 80 to the first capacitor and the wire connecting the integrated circuit 80 to the third capacitor. In addition, a wire through which a signal having a different phase from the signals flowing through the two wires is interposed between the two wires. Thus, since interference between the signals flowing between the two wires can be further suppressed, electromagnetic field noise generated by the interference can be further suppressed.

In an exemplary aspect, in the tracker modules 100A, 100B, and 100C, the first capacitor may be a capacitor to which the highest potential is applied among the plurality of capacitors included in the first circuit.

According to this configuration, the wire connected to the first capacitor has the largest amount of charge movement. Meanwhile, by securing a long distance between the wire connected to the first capacitor and the wire connected to the third capacitor, electromagnetic field noise generated by interference between the signals flowing between the two wires can be effectively suppressed.

In an exemplary aspect, in the tracker modules 100A, 100B, and 100C, each of the first capacitor, the second capacitor, and the third capacitor may be adjacent to the integrated circuit 80.

According to this configuration, since the integrated circuit 80 is adjacent to the capacitors of the first circuit, the wires connecting the capacitors to the switches of the first circuit can be shortened. Thus, parasitic resistance and parasitic inductance of the wires in the first circuit can be decreased. Thus, electromagnetic field noise generated by interference among a plurality of adjacent wires can be suppressed. In an exemplary aspect, since the plurality of high-accuracy and stable second voltages can be supplied to the second circuit from the first circuit, deterioration of the output waveform of the power supply voltage V_{ET} output from the tracker module can be suppressed.

In an exemplary aspect, the communication device 7 according to the present disclosure includes the RFIC 5 that processes a radio frequency signal, the power amplifier circuit 2 that transmits the radio frequency signal between the RFIC 5 and the antenna 6, and any of the tracker modules 100A, 100B, and 100C that supply the power supply voltage V_{ET} to the power amplifier circuit 2.

According to this configuration, the communication device 7 can achieve the same effect as the effects of the tracker modules 100A, 100B, and 100C.

It should be noted that while the tracker module and the communication device according to the present disclosure have been described above based on the embodiments and on the examples in FIGS. 1-8, the tracker module and the communication device according to the present disclosure are not limited to the embodiment and the examples in FIGS. 1-8. Thus, it should be noted that The present disclosure also includes other embodiments implemented by combining any constituents in the embodiment and in the examples in FIGS. 1-8, modification examples obtained by carrying out various modifications perceived by those skilled in the art to the embodiment and the examples without departing from the gist of the present disclosure, and various devices incorporating the tracker module and the communication device.

For example, in the circuit configurations of the tracker module and the communication device according to the exemplary embodiments in FIGS. 1-8, other circuit elements, wires, and the like may be provided on the paths connecting each circuit element and the signal paths disclosed in the drawings.

The present disclosure can be widely used for communication devices such as a mobile phone as a radio frequency module or a communication device disposed in a front end unit supporting multiple bands.

### REFERENCE SIGNS LIST

1 Power supply circuit
2 Power amplifier circuit
3 Filter
4 PA control circuit
5 RFIC
6 Antenna
7 Communication device
10 Pre-regulator circuit
10A PR switch portion
20 Switched-capacitor circuit
20A SC switch portion
30 Supply modulator
30A OS switch portion
40 Filter circuit
50 Direct current power source
80 Integrated circuit
90 Module laminate
90a, 90b Main surface
91 Resin member
100A, 100B, 100C Tracker module
110, 131, 132, 133, 134, 140 Input terminal
111, 112, 113, 114, 130, 141 Output terminal
115, 116 Inductor connection terminal
117, 120, 135 Control terminal
150 External connection electrode
C10, C11, C12, C13, C14, C15, C16, C20, C30, C40, C51, C52, C61, C62, C63, C64 Capacitor
L51, L52, L53 Inductor
L71 Power inductor
P1, P3 Short edge
P2, P4 Long edge
R51 Resistor
S11, S12, S13, S14, S21, S22, S23, S24, S31, S32, S33, S34, S41, S42, S43, S44, S51, S52, S53, S54, S61, S62, S63, S71, S72 Switch

What is claimed:

1. A tracker module comprising:
a module laminate;
an integrated circuit disposed on the module laminate; and
a plurality of capacitors that are disposed on the module laminate and that includes one or more capacitors in a switched-capacitor circuit that is configured to generate a plurality of discrete voltages based on an input voltage,
wherein the integrated circuit includes a switch that is included in the switched-capacitor circuit and a switch that is included in a supply modulator that is configured to selectively output at least one of the plurality of discrete voltages generated by the switched-capacitor circuit,
wherein the plurality of capacitors include:
a first flying capacitor and a second flying capacitor that are configured to be charged and discharged in a complementary manner by repeating a first phase and a second phase between the first flying capacitor and the second flying capacitor,
a third flying capacitor that is configured to be charged at a same timing as the first flying capacitor and to be discharged at a same timing as the first flying capacitor, and
the second flying capacitor is disposed between the first flying capacitor and the third flying capacitor.

2. The tracker module according to claim 1, wherein the supply modulator is configured to control an output voltage based on an envelope signal of a radio frequency signal.

3. The tracker module according to claim 1, wherein, in a plan view of the module laminate:
a periphery of the first flying capacitor and the third flying capacitor each have a rectangular shape that includes a short edge and a long edge, and
the long edge of the first flying capacitor intersects the long edge of the third flying capacitor.

4. The tracker module according to claim 1, wherein the plurality of capacitors further include:
a smoothing capacitor configured to smooth voltages of the first flying capacitor and the second flying capacitor to reduce fluctuations of the voltages,
wherein the smoothing capacitor is disposed between the first flying capacitor and the third flying capacitor and further coupled to the first flying capacitor and the second flying capacitor.

5. The tracker module according to claim 1, wherein a potential difference between a potential of the second flying capacitor at charging and a potential of the first flying capacitor at charging is a smallest potential difference of potential differences between the potential of the second flying capacitor at charging and potentials of flying capacitors other than the second flying capacitor at charging.

6. The tracker module according to claim 1, wherein the first flying capacitor is a capacitor to which a highest potential is applied among potentials applied to the plurality of capacitors that is included in the switched-capacitor circuit.

7. The tracker module according to claim 1, wherein each of the first flying capacitor, the second flying capacitor, and the third flying capacitor is adjacent to the integrated circuit.

8. The tracker module according to claim 1, wherein the plurality of capacitors further comprises one or more capacitors that are included in a filter circuit and positioned adjacent to the integrated circuit, the filter circuit being configured to filter signals from the supply modulator.

9. The tracker module according to claim 8, further comprising one or more inductors and one or more resistors that are included in the filter circuit.

10. The tracker module according to claim 1, wherein the plurality of capacitors further comprises one or more capacitors that are included in a pre-regulator circuit and positioned adjacent to the integrated circuit, the pre-regulator circuit being configured to convert a voltage from a power source to the input voltage.

11. A tracker module comprising:
a module laminate; and
a first circuit and a second circuit, the first circuit being configured to generate a plurality of discrete voltages based on an input voltage, the second circuit being configured to selectively output at least one of the plurality of discrete voltages generated by the first circuit, wherein:
the first circuit includes:
a first capacitor including a first electrode and a second electrode,
a second capacitor including a third electrode and a fourth electrode,
a third capacitor including a fifth electrode and a sixth electrode, and
a first switch, a second switch, a third switch, a fourth switch, a fifth switch, a sixth switch, a seventh switch, and an eighth switch,
a first end of the first switch and a first end of the third switch are coupled to the first electrode,
a first end of the second switch and a first end of the fourth switch are coupled to the second electrode and the fifth electrode,
a first end of the fifth switch and a first end of the seventh switch are coupled to the third electrode,
a first end of the sixth switch and a first end of the eighth switch are coupled to the fourth electrode,
a second end of the first switch, a second end of the second switch, a second end of the fifth switch, and a second end of the sixth switch are coupled to each other,
a second end of the third switch is coupled to a second end of the seventh switch,
a second end of the fourth switch is coupled to a second end of the eighth switch,
the second circuit includes:
a first output terminal,
a ninth switch coupled to (i) the first output terminal and (ii) the second end of the first switch, the second end of the second switch, the second end of the fifth switch, and the second end of the sixth switch, and
a tenth switch coupled to (i) the first output terminal and (ii) the second end of the third switch and the second end of the seventh switch,
the first switch, the second switch, the third switch, the fourth switch, the fifth switch, the sixth switch, the seventh switch, the eighth switch, the ninth switch, and the tenth switch are included in an integrated circuit,
the first capacitor, the second capacitor, the third capacitor, and the integrated circuit are disposed on the module laminate, and
the second capacitor is disposed between the first capacitor and the third capacitor.

12. The tracker module according to claim 11, wherein, in a plan view of the module laminate:
a periphery of the first capacitor and the third capacitor each have a rectangular shape that includes a short edge and a long edge, and
the long edge of the first capacitor intersects the long edge of the third capacitor.

13. The tracker module according to claim 11, wherein the first circuit further comprises:
a fourth capacitor including a seventh electrode and an eighth electrode,
wherein the seventh electrode is coupled to the second end of the first switch, the second end of the second switch, the second end of the fifth switch, and the second end of the sixth switch,
wherein the eighth electrode is coupled to the second end of the third switch and the second end of the seventh switch or coupled to the second end of the fourth switch and the second end of the eighth switch, and
the fourth capacitor is disposed between the first capacitor and the third capacitor.

14. The tracker module according to claim 11, wherein the first capacitor is a capacitor to which a highest potential is applied among potentials applied to a plurality of capacitors included in the first circuit.

15. The tracker module according to claim 11, wherein the first capacitor is disposed adjacent to a first side of the integrated circuit, and the second capacitor and the third capacitor are disposed adjacent to a second side of the integrated circuit.

16. The tracker module according to claim 11, further comprising a third circuit configured to convert a voltage from a power source to the input voltage, the third circuit including one or more switches that are included in the integrated circuit.

17. A communication device comprising:
a signal processing circuit configured to process a radio frequency signal;
a power amplifier circuit configured to transmit the radio frequency signal between the signal processing circuit and an antenna; and
a tracker module configured to supply a power supply voltage to the power amplifier circuit, wherein the tracker module comprises:
a module laminate;
an integrated circuit disposed on the module laminate; and
a plurality of capacitors that are disposed on the module laminate and that includes one or more capacitors in a switched-capacitor circuit that is configured to generate a plurality of discrete voltages based on an input voltage,
wherein the integrated circuit includes a switch that is included in the switched-capacitor circuit and a switch that is included in the supply modulator that is configured to selectively output at least one of the plurality of discrete voltages generated by the switched-capacitor circuit,
wherein the plurality of capacitors include:
a first flying capacitor and a second flying capacitor that are configured to be charged and discharged in a complementary manner by repeating a first phase and a second phase between the first flying capacitor and the second flying capacitor,
a third flying capacitor that is configured to be charged and discharged at a same timing as the first flying capacitor, and
wherein the second flying capacitor is disposed between the first flying capacitor and the third flying capacitor.

18. The communication device according to claim 17, wherein the supply modulator is configured to control an output voltage based on an envelope signal of a radio frequency signal.

19. The communication device according to claim 17, wherein, in a plan view of the module laminate:
a periphery of the first flying capacitor and the third flying capacitor each have a rectangular shape that includes a short edge and a long edge, and
the long edge of the first flying capacitor intersects the long edge of the third flying capacitor.

20. The communication device according to claim 17, wherein the plurality of capacitors further include a smoothing capacitor configured to smooth voltages of the first flying capacitor and the second flying capacitor to reduce fluctuations of the voltages, and wherein the smoothing capacitor is disposed between the first flying capacitor and the third flying capacitor and further coupled to the first flying capacitor and the second flying capacitor.
